(19) United States
(12) Patent Application Publication
(10) Pub. No.: US 2026/0025892 A1
(43) Pub. Date: Jan. 22, 2026

(54) LED DRIVING MODULE

(71) Applicant: SEOUL VIOSYS CO., LTD., Ansan-si (KR)

(72) Inventors: Ok Hwan KWON, Ansan-si (KR); Kwang Bea LIM, Ansan-si (KR)

(73) Assignee: SEOUL VIOSYS CO., LTD., Ansan-si (KR)

(21) Appl. No.: 18/997,288

(22) PCT Filed: Jul. 21, 2023
(86) PCT No.: PCT/KR2023/010579

§ 371 Date: Jan. 21, 2025

(30) Foreign Application Priority Data
Jul. 22, 2022 (KR) 10-2022-0091136

(51) Int. Cl. H05B 45/56

(52) U.S. Cl. CPC H05B 45/56

(57) ABSTRACT

An LED driving module is provided with an ultraviolet LED and a fault sensing unit. The fault sensing unit senses a fault of the ultraviolet LED. The fault sensing unit includes a connection sensing unit configured to sense a connection state of the ultraviolet LED. Further, the connection sensing unit outputs a fault signal through the fault signal output terminal when a fault occurs in the ultraviolet LED due to a short state or an opening state of the ultraviolet LED.

### TECHNICAL FIELD

The present invention relates to an LED driving module.

### BACKGROUND ART

With various advantages including small size, high luminous efficacy, long lifespan, and low manufacturing costs, light emitting diodes (LEDs) have replaced conventional light bulbs as means for lighting and display.

LEDs can be classified into infrared LEDs configured to emit infrared light, visible LEDs configured to emit visible light, and ultraviolet LEDs configured to emit ultraviolet light. Ultraviolet (UV) LEDs have been applied to a variety of products after it was found that UV light can kill DNA or RNA bacteria. In recent years, compact products employing a single light emitting diode have been developed in consideration of storage and portability.

Typically, such products may be provided with a separate light emitting diode and a driving module for driving the light emitting diode.

When a fault occurs in a product employing a light emitting diode, it is difficult to immediately determine whether the fault is caused by a fault of the light emitting diode or another component.

### TECHNICAL PROBLEM

It is one aspect of the present invention to provide an LED driving module configured to sense a faulty state of an ultraviolet LED and to output a fault signal to indicate a fault of the ultraviolet LED.

It is another aspect of the present invention to provide an LED driving module configured to output a fault signal based on which the type of fault that has occurred in the ultraviolet LED can be determined.

It is a further aspect of the present invention to provide an LED driving module that is suitable for small products to which a single ultraviolet LED is applied while detecting a fault of the ultraviolet LED.

### TECHNICAL SOLUTION

In accordance with one aspect of the present invention, there is provided an LED driving module provided with a single ultraviolet LED and including a fault sensing unit. The fault sensing unit may be configured to sense a fault of the ultraviolet LED. The fault sensing unit may include a connection sensing unit configured to sense a connection state of the ultraviolet LED. In addition, the connection sensing unit may output a fault signal through a fault signal output terminal when a fault occurs due to short or opening of the ultraviolet LED.

The connection sensing unit may include a connection sensing switch turned on and turned off corresponding to a voltage of a node connected to the ultraviolet LED.

The node connected to the ultraviolet LED may be connected to an anode terminal of the ultraviolet LED. In addition, the connection sensing switch may include a first end, a second end, and a third end through which signals are input or output. Here, a voltage corresponding to the voltage of the node may be applied to the first end to turn on and turn off the connection sensing switch. The second end may be connected to the fault signal output terminal. The third end may be connected to ground.

For example, the fault signal output terminal may include a first fault signal output terminal and a second fault signal output terminal. The first fault signal output terminal may output a first fault signal when the ultraviolet LED is in a short state. The second fault signal output terminal may output a second fault signal when the ultraviolet LED is in an open state.

The first fault signal output terminal may be connected to a node connecting the second end of the connection sensing switch and one end of a resistor. The second fault signal output terminal may be connected to a node connecting two resistors in series between the anode terminal of the ultraviolet LED and ground. The resistor connected to the second end of the connection sensing switch may be connected at the other end thereof to ground.

The fault sensing unit may further include a heat sensing unit configured to sense a heating state of the ultraviolet LED.

The heat sensing unit may include: a thermal resistor whose resistance varies depending on ambient temperature: and a heat sensing switch connected to the thermal resistor. The thermal resistor may be connected to the anode terminal of the ultraviolet LED. The heat sensing switch may be turned on and turned off in response to a voltage varying according to resistance of the thermal resistor.

The heat sensing switch may include a first end, a second end, and a third end through which signals are input or output. The first end may receive a voltage varying according to resistance of the thermal resistor. The second end may be connected to the fault signal output terminal. The third end may be connected to ground.

For example, the fault signal output terminal may include a first fault signal output terminal, a second fault signal output terminal, and a third fault signal output terminal. The first fault signal output terminal may output a first fault signal when the ultraviolet LED is in a short state. The second fault signal output terminal may output a second fault signal when the ultraviolet LED is in an open state. The third fault signal output terminal may output a third fault signal when the ultraviolet LED is in an overheating state.

The first fault signal output terminal may be connected to a node connecting the second end of the connection sensing switch to one end of a resistor. The second fault signal output terminal may be connected to a node connecting two resistors in series between the anode terminal of the ultraviolet LED and ground. The third fault signal output terminal may be connected to a node connecting the second end of the heat sensing switch to one end of a resistor. Each of the resistor connected to the second end of the connection sensing switch and the resistor connected to the second end of the heat sensing unit may be connected at the other end thereof to ground.

The connection sensing unit may include an opening sensing unit configured to sense an open state of the ultraviolet LED and a short sensing unit configured to sense a short state of the ultraviolet LED.

Each of the opening sensing unit and the short sensing unit may include an amplifier configured to compare a reference voltage with an input voltage and at least a switch turned on and off by an output signal of the amplifier.

The opening sensing unit may include an opening sensing switch. The opening sensing switch may include a first end, a second end, and a third end through which signals are input or output. The first end may receive a voltage for turning on and turning off the switch in response to a signal output from the amplifier of the opening sensing unit. The second end may be connected to the fault signal output terminal. The third end may allow a current input through the first end to pass therethrough when the opening sensing switch is in a turn-on state.

The short sensing unit may include a short sensing switch. The short sensing switch may include a first end, a second end, and a third end through which signals are input or output. The first end may receive a voltage for turning on and turning off the switch in response to a signal output from an amplifier of the short sensing unit. The second end may be connected to the fault signal output terminal. The third end may allow a current input through the first end to pass therethrough when the short sensing switch is in a turn-on state.

The fault signal output terminal may output a normal signal when the ultraviolet LED is in a normal state.

The fault signal may be a lower voltage than the normal signal.

The LED driving module may further include a Zener diode connected at one end thereof to the fault signal output terminal and at the other end thereof to ground. Here, the normal signal may be a Zener voltage.

The LED driving module may further include a current sensing unit and a control signal generator. The current sensing unit may be configured to sense a current supplied to the ultraviolet LED. The control signal generator may be configured to generate and output a signal to control a switch according to a current value sensed by the current sensing unit. The control signal generator may output a short signal to the switch to turn on the switch and an open signal to turn off the switch. The connection sensing unit may sense the short signal and the open signal output from the control signal generator to the switch. Here, the fault sensing unit may generate and output a fault signal when the short signal or the open signal sensed by the connection sensing unit is sensed for a preset period of time or more.

The fault sensing unit may further include a heat sensing unit configured to sense a temperature of the ultraviolet LED or an ambient temperature of the ultraviolet LED. The fault sensing unit may generate and output a fault signal when the temperature sensed by the heat sensing unit is greater than or equal to a preset temperature.

The LED driving module may further include a constant current unit configured to supply a constant current to the ultraviolet LED.

### ADVANTAGEOUS EFFECTS

According to embodiments of the present invention, an LED driving module configured to sense a faulty state of a UV LED can determine whether a fault occurs in the UV LED.

In addition, according to the embodiments, the LED driving module outputs a signal according to the type of failure that has occurred in the UV LED, whereby a faulty state of the UV LED can be accurately identified.

Further, according to the embodiments, the LED driving module may be suitable for small products by realizing a simple circuit configured to sense a fault of the LED to minimize increase in size thereof.

### DESCRIPTION OF DRAWINGS

FIG. 1 is a schematic block diagram of an LED driving module according to a first embodiment of the present invention.

FIG. 2 is a block diagram of the LED driving module according to the first embodiment of the present invention.

FIG. 3 is a circuit diagram of a fault sensing unit of the LED driving module according to the first embodiment of the present invention.

FIG. 4 is a block diagram illustrating functions of an LED driving module according to a second embodiment of the present invention.

FIG. 5 is a circuit diagram of the LED driving module according to the second embodiment of the present invention.

FIG. 6 is a schematic block diagram of an LED driving module according to a third embodiment of the present invention.

FIG. 7 is a circuit diagram of an LED driving module according to a fourth embodiment of the present invention.

FIG. 8 is a block diagram of an LED driving module according to a fifth embodiment of the present invention.

FIG. 9 is a schematic block diagram of a system of an ultraviolet LED device according to one embodiment of the present invention.

FIG. 10 is a schematic block diagram of a system of an ultraviolet LED device according to another embodiment of the present invention.

### DETAILED DESCRIPTION

Hereinafter, embodiments of the present invention will be described with reference to the accompanying drawings. It should be understood that the following embodiments are provided for complete disclosure and thorough understanding of the present invention by those skilled in the art. Accordingly, the present invention is not limited to the following embodiments and may be embodied in different ways. In addition, the drawings may be exaggerated in width, length, and thickness of components for descriptive convenience and clarity only. Like components will be denoted by like reference numerals throughout the specification.

Hereinafter, an LED driving module according to the present invention will be described in detail with reference to the drawings.

LED driving modules according to embodiments of the present invention are applied to small products employing ultraviolet LEDs. The LED driving modules according to the embodiments of the present invention may sense a fault of an ultraviolet LED, and generate and output a fault signal. More specifically, the LED driving modules may output a normal signal indicating a normal state and a fault signal indicating a faulty state depending on the state of the ultraviolet LED. Hereinafter, description of various embodiments of the present invention with reference to the drawings will focus on a fault sensing unit configured to sense a fault of the ultraviolet LED.

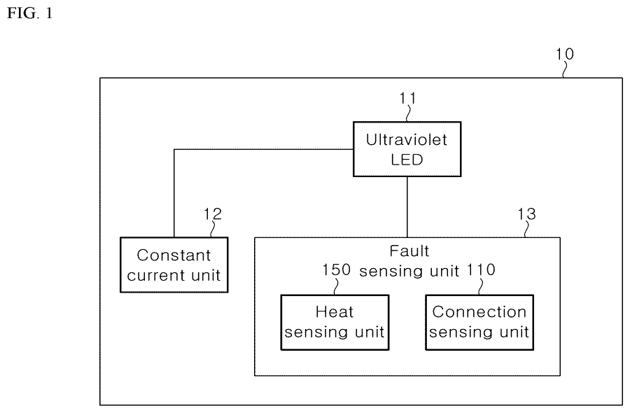

FIG. 1 to FIG. 3 are views of an LED driving module according to a first embodiment of the present invention.

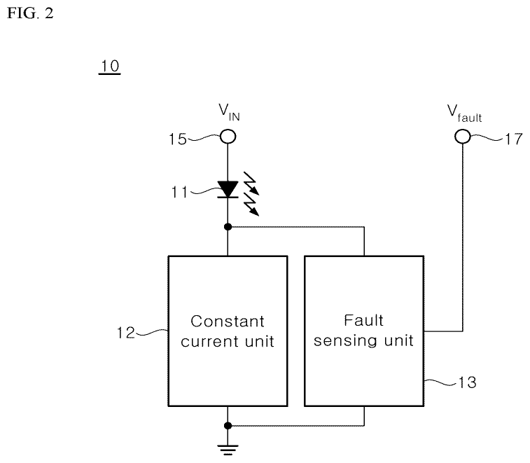

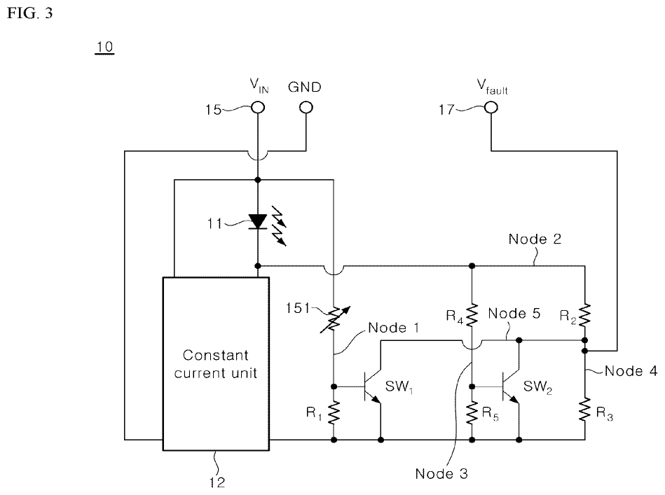

FIG. 1 is a schematic block diagram of an LED driving module according to a first embodiment of the present invention. FIG. 2 is a schematic block diagram of the LED driving module according to the first embodiment of the present invention. FIG. 3 is a circuit diagram of a fault sensing unit of the LED driving module according to the first embodiment of the present invention.

Referring to FIG. 1 to FIG. 3, the LED driving module 10 according to the first embodiment of the present invention may include an ultraviolet LED 11, a constant current unit 12, and a fault sensing unit 13. Referring to FIG. 2, in the LED driving module 10 according to the first embodiment, the constant current unit 12 may be disposed at the rear end of the ultraviolet LED 11. That is, in the LED driving module 10 according to the first embodiment, the constant current unit 12 may be connected to a cathode terminal of the ultraviolet LED 11 to control a current flowing in the ultraviolet LED 11.

The LED driving module 10 according to this embodiment is a module to be applied to small products and may include one ultraviolet LED 11.

The constant current unit 12 enables a constant current to flow in the ultraviolet LED 11 when the ultraviolet LED 11 is turned on. The constant current unit 12 may control the current flowing in the ultraviolet LED 11 to be constant such that the intensity of UV light emitted from the ultraviolet LED 11 is constant.

The constant current unit 12 may be realized as a circuit of various structures using resistors, transistors, diodes, Zener diodes, and the like. The constant current unit 12 according to this embodiment may include any of constant current circuits known to those skilled in the art.

The fault sensing unit 13 may be configured to sense a fault that has occurred in the ultraviolet LED 11.

According to this embodiment, the fault sensing unit 13 may include a connection sensing unit 110 and a heat sensing unit 150.

The connection sensing unit 110 may be configured to sense an abnormality in a connection state of the ultraviolet LED 11. That is, the connection sensing unit 110 may be configured to sense failure of the connection state, such as opening and short circuit of the ultraviolet LED 11.

The heat sensing unit 150 may be configured to sense a heating state of the ultraviolet LED 11 by detecting an ambient temperature. When the ultraviolet LED 11 emits UV light, the ultraviolet LED 11 may generate heat due to various causes, such as contact between a semiconductor and a metal, lattice vibration (phonon), heat conversion of light reabsorbed by total reflection from the surface, leakage current, and the like. When the ultraviolet LED 11 emits heat, the ambient temperature of the ultraviolet LED 11 increases. When the ambient temperature of the ultraviolet LED 11 increases, the ambient temperature of other devices including the LED driving module 10 also increases. That is, the heat sensing unit 150 can detect a fault of the ultraviolet LED 11 by sensing a change in ambient temperature.

As such, the fault sensing unit 13 may sense a heating state and the connection state between the anode terminal and the cathode terminal of the ultraviolet LED 11 and may output a fault signal indicating an abnormal state when the abnormal state is sensed. Further, the fault sensing unit 13 may output a normal signal indicating a normal state of the ultraviolet LED 11 when no fault of the ultraviolet LED 11 is sensed.

Referring to FIG. 2, the LED driving module 10 may include an input terminal 15 that receives signals from the outside and a fault signal output terminal 17 that outputs signals to the outside. According to this embodiment, a driving voltage is supplied to the ultraviolet LED 11 through the input terminal 15. In addition, a fault signal indicating a fault state of the ultraviolet LED 11 may be output through the fault signal output terminal 17. In addition, a normal signal indicating a normal state of the ultraviolet LED 11 may be output through the fault signal output terminal 17.

The constant current unit 12 may be disposed at the rear end of the ultraviolet LED 11. That is, the constant current unit 12 may be connected to the cathode terminal of the ultraviolet LED 11. In addition, the fault sensing unit 13 may also be disposed at the rear end of the ultraviolet LED 11 and may be connected to the cathode terminal of the ultraviolet LED 11.

FIG. 3 is a circuit diagram of the LED driving module 10. Referring to FIG. 3, the circuit constituting the fault sensing unit 13 of the LED driving module 10 may include switches each provided with a plurality of terminals through which signals are input or output. In this embodiment, the switches may be NPN-type bipolar transistors. When the switches are the bipolar transistors, each of the switches may include three terminals through which signals are input or output. For example, the switch may include a first end as a base terminal, a second end as a collector terminal, and a third end as an emitter terminal. Further, the signals input to the switch may be a voltage and a current.

The heat sensing unit 150 according to this embodiment may include a thermal resistor 151, a first switch SW₁, and a first resistor R₁.

The thermal resistor 151 refers to a device whose resistance value changes with change in temperature. For example, the thermal resistor 151 may be a negative temperature coefficient (NTC) thermistor that has characteristics of a negative resistance temperature coefficient, in which the resistance decreases when the temperature increases. That is, according to this embodiment, when the temperature around the thermal resistor 151 is higher than or equal to a certain temperature, the resistance value of the thermal resistor 151 decreases.

The thermal resistor 151 may be connected at a first end thereof to the anode terminal of the ultraviolet LED 11 and connected at a second end thereof to a first end of the first resistor R₁.

The first switch SW₁ may be connected at a first end thereof to a first node (Node 1) to which the second end of the thermal resistor 151 and the first end of the first resistor R₁ are connected. In addition, the first switch SW₁ may be connected at a second end thereof to a second end of the second switch SW₂. Further, the second end of the first switch SW₁ may be connected to the fault signal output terminal 17 that is an output terminal of the fault sensing unit 13.

In addition, a second end of the first resistor R₁ and a third end of the first switch SW₁ may be connected to ground.

According to this embodiment, the connection sensing unit 110 may include a second switch SW₂, a second resistor R₂, a third resistor R₃, and a fifth resistor R₅.

The second resistor R₂ may be connected at a first end thereof to the cathode terminal of the ultraviolet LED 11 and connected at a second end thereof to a first end of the third resistor R₃. That is, the second resistor R₂ and the third resistor R₃ may be connected in series.

A fourth resistor R₄ may be connected at a first end thereof to the cathode terminal of the ultraviolet LED 11. That is, the first end of the fourth resistor R₄ may be connected to a second node (Node 2) to which the cathode terminal of the ultraviolet LED 11 and the first end of the second resistor R₂ are connected. In addition, the fourth resistor R₄ may be connected at a second end thereof to a first end of the fifth resistor R₅. That is, the fourth resistor R₄ and the fifth resistor R₅ may be connected in series. In addition, the fourth resistor R₄ and the fifth resistor R₅ may be connected in parallel to the second resistor R₂ and the third resistor R₃.

The second switch SW₂ may be connected at a first end thereof to a third node (Node 3), to which the second end of the fourth resistor R₄ and the first end of the fifth resistor R₅ are connected. In addition, the second switch SW₂ may be connected at a second end thereof to a fourth node (Node 4) to which the second resistor R₂ and the third resistor R₃ are connected, and to a fifth node (Node 5) to which the second end of the first switch SW₁ is connected. That is, the second end of the second switch SW₂ may be connected to the fault signal output terminal 17 of the fault sensing unit 13.

A second end of the fifth resistor R₅, a third end of the second switch SW₂, and a second end of the third resistor R₃ may be connected to ground.

In the fault sensing unit 13 according to this embodiment, the heat sensing unit 150 and the connection sensing unit 110 may be connected to the fault signal output terminal 17. That is, the fault sensing unit 13 may be formed such that the heat sensing unit 150 and the connection sensing unit 110 share the same fault signal output terminal 17. Thus, the fault sensing unit 13 may output a fault signal when any of a fault caused by heat generation of the ultraviolet LED 11 and a fault caused by the connection state is sensed.

According to this embodiment, the fault sensing unit 13 may allow a voltage at the fault signal output terminal 17 to become 0 V when the ultraviolet LED 11 fails due to heat generation or the connection state. That is, the fault sensing unit 13 of the LED driving module 10 according to this embodiment may be designed such that 0 V output from the fault signal output terminal 17 becomes a fault signal indicating a fault of the ultraviolet LED 11.

When the ultraviolet LED 11 generates heat, the ambient temperature of the ultraviolet LED 11 increases. Since the LED driving module 10 according to this embodiment is a compact device, the ambient temperature of the thermal resistor 151 also increases due to heat generation of the ultraviolet LED 11. Accordingly, the heat sensing unit 150 according to this embodiment can sense the degree of heat generation from the ultraviolet LED 11 based on the ambient temperature sensed by the thermal resistor 151.

For example, the thermal resistor 151 of the heat sensing unit 150 may decrease in resistance when the ambient temperature increases. In addition, a voltage distributed by the thermal resistor 151 and the first resistor Rᵢ may be applied to the first end of the first switch SW₁. When the resistance value of the thermal resistor 151 decreases due to increase in ambient temperature, the voltage applied to the first end of the first switch SW₁ also increases.

When a voltage higher than a preset operation voltage of the first switch SW₁ is applied to the first end of the first switch SW₁, the first switch SW₁ may be turned on. Here, the operation voltage refers to a reference voltage at which the first switch SW₁ is turned on or turned off. As such, in this embodiment, the operation voltage may be a reference for distinguishing between normal heating and abnormal overheating of the ultraviolet LED 11. For example, the operation voltage of the switches may be set as a threshold voltage. The first switch SW₁ of the heat sensing unit 150 is a heat sensing switch that operates according to the heating temperature of the ultraviolet LED 11.

When the first switch SW₁ is turned on, a current flowing through the fourth node (Node 4) may pass through the first switch SW₁ and the voltage at the fault signal output terminal 17 may become 0 V.

As such, the heat sensing unit 150 according to this embodiment may generate a fault signal indicating a fault of the ultraviolet LED 11 by allowing the first switch SW1 to be turned on when the ambient temperature is increased above a certain temperature by the ultraviolet LED 11. Here, the certain temperature refers to a reference temperature with respect to an overheating state that occurs when the ultraviolet LED 11 is abnormal.

When the ultraviolet LED 11 is in a normal heating state, a voltage to maintain the first switch SW1 in a turn-off state is applied to the first end of the first switch SW1. That is, when the ultraviolet LED 11 is in a normal heating state, the first switch SW₁ is kept in the turn-off state.

According to this embodiment, the connection sensing unit 110 may sense a fault caused by the connection state of the ultraviolet LED 11. That is, the connection sensing unit 110 may sense short circuit and opening of the ultraviolet LED 11.

The connection sensing unit 110 may allow the voltage at the fault signal output terminal 17 to become 0 V when the ultraviolet LED 11 is in a short state.

The second switch SW₂ is connected at the first end thereof to the third node (Node 3). Thus, the second switch SW₂ may be turned on or off depending on the voltage at the third node (Node 3).

For example, the second switch SW₂ may be in a turn-off state when the voltage at the first end thereof is less than a preset operation voltage. In addition, the second switch SW₂ may be turned on when the voltage at the first end thereof is greater than or equal to the preset operation voltage. As such, the preset operation voltage may become a reference for defining a short state of the ultraviolet LED 11. The operation voltage may be a threshold voltage of the second switch SW₂. The second switch SW₂ is a connection sensing switch that operates according to the connection state of the ultraviolet LED 11.

When the ultraviolet LED 11 is in a normal state, the second node (Node 2) has a voltage corresponding to a voltage drop from a driving voltage to the operation voltage of the ultraviolet LED 11. When the ultraviolet LED 11 is in a normal state, a voltage smaller than the preset operation voltage may be applied to the first end of the second switch SW₂. Here, the second switch SW₂ may be kept in a turn-off state.

When the second switch SW₂ is kept in a turn-off state, a current flows through the fourth node (Node 4) connecting the second resistor R₂ to the third resistor R₃. Here, the fault signal output terminal 17 may output a voltage distributed by the second resistor R₂ and the third resistor R₃. For example, when the ultraviolet LED 11 is in a normal state, the voltage at the fault signal output terminal 17 may be calculated according to Equation 1.

$${V}_{fault} = ( {V}_{IN} - {V}_{LED} ) \cdot ( {R}_{3} / ( {R}_{2} + {R}_{3} ) ) \qquad [ Equation 1 ]$$

Here, V_{fault} denotes a voltage output from the fault signal output terminal 17 and corresponds to a fault signal. V_{IN} denotes a driving voltage supplied through the input terminal 15, V_{LED} denotes the operation voltage of the ultraviolet LED, R₂ denotes the second resistor, and R₃ denotes the third resistor.

When the ultraviolet LED 11 is in a short state, the voltage at the second node 2 may be the same as the driving voltage. That is, when the ultraviolet LED 11 is in a short state, a higher voltage is applied to the second node 2 than when the ultraviolet LED 11 is in a normal state. Then, the second switch SW₂ may be turned on by a voltage at the first end thereof, which is higher than or equal to the operation voltage.

When the second switch SW₂ is turned on, the current flows to ground through the second resistor R₂ and the second switch SW₂ and the voltage at the fault signal output terminal 17 may become 0 V.

In addition, when the ultraviolet LED 11 is in an open state, the voltage at the second node 2 is 0 V. Accordingly, the voltage at the fault signal output terminal 17 may become 0 V.

When the ultraviolet LED 11 is in a short state and in an open state, the connection sensing unit 110 may output 0 V corresponding to a fault signal to the fault signal output terminal 17.

As such, the LED driving module 10 according to this embodiment may output a normal signal corresponding to a voltage of (V_{IN}−V_{LED}) (R₁/(R₁+R₂)) to the fault signal output terminal 17 when the ultraviolet LED 11 is normal both in heat generation and connection thereof. Further, the LED driving module 10 may output a fault signal corresponding to a voltage of 0 V to the fault signal output terminal 17 when the ultraviolet LED 11 is in any one state among a short state, an open state, and an abnormal heating state.

The fault sensing unit 13 of the LED driving module 10 according to this embodiment allows 0 V to be output from the fault signal output terminal 17 when a fault occurs in the ultraviolet LED 11, but is not limited thereto. For example, the fault sensing unit 13 may include a circuit adapted to output an arbitrary voltage other than 0 V as a fault signal. That is, the fault signal of the fault sensing unit 13 may be a preset voltage output when a fault occurs in the ultraviolet LED 11. Here, the fault sensing unit 13 may output a normal signal distinguished from the fault signal when the ultraviolet LED 11 is in a normal state. That is, the fault sensing unit 13 of the LED driving module 10 according to this embodiment may be configured with a circuit capable of outputting signals that can distinguish between when the ultraviolet LED 11 is in a normal state and when the ultraviolet LED 11 is in a faulty state.

As such, the LED driving module 10 according to this embodiment includes the fault sensing unit 13 that outputs a signal capable of distinguishing between when the ultraviolet LED 11 is in a normal state and when the ultraviolet LED 11 is in a faulty state. Thus, when a fault occurs in a product employing the LED driving module 10, it is possible to distinguish whether the fault is caused by the ultraviolet LED 11 or by other components. Accordingly, when a signal indicating a fault of the ultraviolet LED 11 is output, it is possible to easily solve a problem of a defective product by replacing the ultraviolet LED 11 without checking whether the other components are defective.

In this embodiment, the thermal resistor 151 is described as an NTC by way of example. However, the heat sensing unit 150 according to this embodiment is not limited thereto. For example, the thermal resistor 151 of the heat sensing unit 150 may be a positive temperature coefficient (PTC) thermistor having characteristics of a constant resistance temperature coefficient such that the resistance value increases as the temperature increases. Here, the first switch SW1 of the heat sensing unit 150 may be set to be turned on at a preset operation voltage or less.

In the LED driving module 10 according to this embodiment, the switches in the fault sensing unit 13 are described as NPN type bipolar transistors by way of example. However, it should be understood that the type of switches applied to this embodiment is not limited to the NPN type bipolar transistor. For example, the switches of the fault sensing unit 13 may be configured with diodes or MOSFETs. Alternatively, the switches may be transistors that are turned on at a lower voltage than the operation voltage or threshold voltage. As such, the switches may be any devices that are turned on or off in response to an input signal.

As such, the fault sensing unit 13 according to this embodiment may be implemented in various ways so long as the fault sensing unit is capable of sensing a normal state and a faulty state of the ultraviolet LED 11 and outputting a signal capable of distinguishing the normal state and the faulty state.

The LED driving module 10 according to this embodiment may be applied to a small product employing a single UV LED 11. As the demand for small products increases, the LED driving module 10 according to this embodiment also maintains the size for small products. Furthermore, the LED driving module 10 according to this embodiment includes the fault sensing unit 13 configured to sense an abnormality of the ultraviolet LED 11 and to generate a signal corresponding to the abnormality.

The LED driving module 10 according to this embodiment is realized to sense a fault of the ultraviolet LED 11 through a simple circuit. Accordingly, the LED driving module 10 according to this embodiment can sense a fault of the ultraviolet LED 11 and output a signal indicating the fault while maintaining the size of a conventional LED driving module.

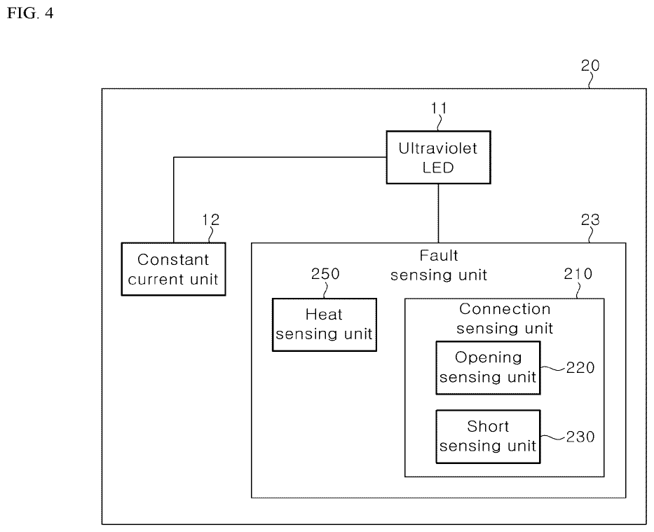

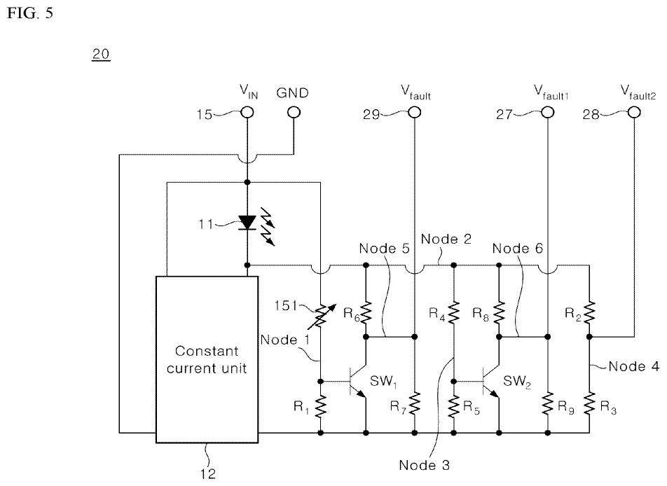

FIG. 4 and FIG. 5 are views of an LED driving module according to a second embodiment of the present invention.

FIG. 4 is a block diagram illustrating functions of the LED driving module according to the second embodiment. FIG. 5 is a schematic diagram of the LED driving module according to the second embodiment.

Referring to FIG. 4 and FIG. 5, the LED driving module 20 according to the second embodiment includes a constant current unit 12 and a fault sensing unit 23.

The fault sensing unit 23 according to this embodiment may include a heat sensing unit 250 and a connection sensing unit 210. The connection sensing unit 210 according to this embodiment includes an opening sensing unit 220 and a short sensing unit 230.

The fault sensing unit 23 according to this embodiment may output signals through the heat sensing unit 250, the opening sensing unit 220, and the short sensing unit 230, respectively. That is, the fault sensing unit 23 may sense a faulty state of the ultraviolet LED 11 and may output a signal capable of distinguishing the type of fault sensed.

Referring to FIG. 5, the fault sensing unit 23 according to this embodiment may be configured to sense a heating state, a short state, and an open state of the ultraviolet LED 11 and to output a signal corresponding to each state.

The heat sensing unit 250 according to this embodiment may include a thermal resistor 151, a first switch SW₁, a first resistor R₁, a sixth resistor R₆, and a seventh resistor R₇.

The thermal resistor 151 may be connected at a first end thereof to the anode terminal of the ultraviolet LED 11 and connected at a second end thereof to a first end of the first resistor R₁. The thermal resistor 151 and the first resistor R₁ may be connected to each other in series.

The sixth resistor R₆ may be connected at a first end thereof to the cathode terminal of the ultraviolet LED 11 and connected at a second end thereof to a second end of the first switch SW₁.

The first switch SW₁ may be connected at a first end thereof to a first node (Node 1) to which the thermal resistor 151 and the first resistor R₁ are connected, and may be connected at a second end thereof to a second end of the sixth resistor R₆.

The seventh resistor R₇ may be connected at a first end thereof to the second end of the first switch SW₁ and may be connected to the first switch SW₁ in parallel.

In the heat sensing unit 250, a second end of the first resistor R₁, a third end of the first switch SW₁ and a second end of the seventh resistor R₇ may be connected to ground.

The heat sensing unit 250 may output a third fault signal and a normal signal through a node to which the first switch SW₁ and the seventh resistor R₇ are connected. That is, the heat sensing unit 250 may be formed with a third fault signal output terminal 29 that outputs a signal regarding a heating state of the ultraviolet LED 11 to a fifth node (Node 5) to which the second end of the first switch SW₁ and the third resistor R₃ are connected.

The connection sensing unit 210 according to this embodiment may include a second resistor R₂, a third resistor R₃, a fourth resistor R₄, a fifth resistor R₅, an eighth resistor R₈, a ninth resistor R₉, and a second switch SW₂.

The second resistor R₂ may be connected at a first end thereof to the cathode terminal of the ultraviolet LED 11. In addition, each of the fourth resistor R₄ and the eighth resistor R₅ may be connected at a first end thereof to a second node (Node 2) to which the cathode terminal of the ultraviolet LED 11 and the second resistor R₂ are connected.

The second resistor R₂ may be connected at a second end thereof to a first end of the third resistor R₃. The fourth resistor R₄ may be connected at a second end thereof to a first end of the fifth resistor R₅. In addition, the eighth resistor R₅ may be connected at a second end thereof to a second end of the second switch SW₂. Here, a second end of the third resistor R₃, a second end of the fifth resistor R₅, and a third end of the second switch SW₂ may be connected to ground. In addition, the second switch SW₂ may be connected at a first end thereof to a third node (Node 3) to which the fourth resistor R₄ and the fifth resistor R₅ are connected.

The connection sensing unit 210 according to this embodiment may output a first fault signal indicating an abnormal connection state of the ultraviolet LED 11 through a sixth node (Node 6) to which the second end of the second switch SW₂ and the ninth resistor R₉ are connected. That is, a first fault signal output terminal 27 may be formed at the node to which the second end of the second switch SW₂ and the ninth resistor R₉ are connected.

Further, the connection sensing unit 210 according to this embodiment may output a second fault signal indicating an abnormal connection state of the ultraviolet LED 11 through a fourth node (Node 4) to which the second resistor R₂ and the third resistor R₅ are connected. That is, a second fault signal output terminal 28 may be formed at the node to which the second resistor R₂ and the third resistor R₃ are connected.

In the block diagram of FIG. 4, although the short sensing unit 230 and the opening sensing unit 220 are shown as separate configurations, these configurations are provided to distinguish the functions of the connection sensing unit 210. That is, the connection sensing unit 210 may output signals corresponding to the open state and the short state of the ultraviolet LED 11 according to operation of one switch, as shown in FIG. 5.

When the heating state of the ultraviolet LED 11 is normal, the ambient temperature of the thermal resistor 151 may also be within a normal temperature range. When the ambient temperature of the thermal resistor 151 is normal, a voltage is applied to the first end of the first switch SW₁ such that the first switch SW₁ can be kept in a turn-off state. When the first switch SW₁ is in the turn-off state, a current flows in the sixth resistor R₆ and the seventh resistor R₇. Thus, when the heating state of the ultraviolet LED 11 is normal, a normal signal, which is a certain voltage applied to the fifth node (Node 5), may be output from the third fault signal output terminal 29. In this embodiment, the voltage that is a normal signal output from the third fault signal output terminal 29 may be determined by the voltage of the second node 2, the sixth resistor R₆, and the seventh resistor R₇.

When the ambient temperature of the thermal resistor 151 increases such that the voltage applied to the first end of the first switch SW₁ is higher than or equal to a preset operation voltage, the first switch SW₁ may be turned on. When the first switch SW₁ is turned on, a current may flow through the sixth resistor R₆ and the first switch SW₁, and the voltage at the fifth node 5 may become 0 V. That is, when the ultraviolet LED 11 is in an overheating state outside the normal range, the heat sensing unit 250 may output 0 V as a third fault signal through the third fault signal output terminal 29.

The heat sensing unit 250 according to this embodiment may detect an overheating state of the ultraviolet LED 11 regardless of the connection state of the ultraviolet LED 11. That is, when the ultraviolet LED 11 is in an abnormal overheating state, a third fault signal is output from the third fault signal output terminal 29.

When the ultraviolet LED 11 operates in a normal connection state, the second node (Node 2) has a voltage corresponding to a voltage drop from a driving voltage to the operation voltage of the ultraviolet LED 11. Here, a low voltage may be applied to the first end of the second switch SW₂ to maintain the turn-off state of the second switch SW₂. That is, when the ultraviolet LED 11 is in the normal connection state, the second switch SW₂ may be kept in the turn-off state. When the second switch SW₂ is in the turn-off state, a current flows through the node 6 to which the eighth resistor R₅ and the ninth resistor R₉ are connected. Here, a signal output from the first fault signal output terminal 27 may be any voltage greater than 0 V.

In addition, when the second switch SW₂ is in the turn-off state, a current flows through the fourth node (Node 4) to which the second resistor R₂ and the third resistor R₃ are connected. Here, a signal output from the second fault signal output terminal 28 may be any voltage greater than 0 V.

As such, when the connection state of the ultraviolet LED 11 is normal, the connection sensing unit 210 according to this embodiment may output normal signals, which are any voltages greater than 0 V, through the first fault signal output terminal 27 and the second fault signal output terminal 28, respectively.

The second node (Node 2) has a greater voltage when the ultraviolet LED 11 is in a short state than when the ultraviolet LED 11 is in a normal state. For example, when the ultraviolet LED 11 is in a short state, the voltage at second node (Node 2) may be the same as the driving voltage. As the voltage at the second node (Node 2) increases, the voltage applied to the first end of the second switch SW₂ also increases. When a voltage greater than the operation voltage of the second switch SW₂ is applied to the first end of the second switch SW₂, the second switch SW₂ may be turned on.

When the second switch SW₂ is turned on, the current having passed through the eighth resistor R₅ passes through the second switch SW₂ and the voltage of the first fault signal output from the sixth node (Node 6) may become 0 V. Accordingly, the first fault signal output terminal 27 may output the first fault signal that is 0 V.

A current may flow in the fourth node (Node 4) to which the second resistor R₂ and the third resistor R₃ are connected. Here, the voltage at the fourth node (Node 4) may be any voltage greater than 0 V due to the voltage at the second node (Node 2), the second resistor R₂, and the third resistor R₃. Thus, the second fault signal output terminal 28 may output a normal signal that is a certain voltage greater than 0 V. According to this embodiment, this voltage may be set by the resistors and switches constituting the circuit.

As such, the fault sensing unit 23 according to this embodiment may output a first fault signal through the first fault signal output terminal 27 and a normal signal through the second fault signal output terminal 28 when the ultraviolet LED 11 is in a short state.

When the ultraviolet LED 11 is in an open state, the voltage at the second node (Node 2) may be much smaller than when the ultraviolet LED 11 is in a normal state. For example, when the ultraviolet LED 11 is in an open state, the voltage at second node (Node 2) may be 0 V.

Since the voltage at the second node (Node 2) is 0 V, the voltages at the fourth node (Node 4) and the sixth node (Node 6) may also be 0 V. Therefore, a first fault signal and a second fault signal, which are 0 V, may be output from the first fault signal output terminal 27 and the second fault signal output terminal 28, respectively.

As such, the fault sensing unit 23 according to this embodiment may output the first fault signal through the first fault signal output terminal 27 and the second fault signal through the second fault signal output terminal 28 when the ultraviolet LED 11 is in an open state.

Table 1 shows signals output from the fault sensing unit 23 according to the state of the ultraviolet LED 11.

TABLE 1

| | | First fault | Second fault | Third fault |
|---|---|---|---|---|
| | | signal | signal | signal |
| Temperature | Connection | output | output | output |
| state | state | terminal | terminal | terminal |
| Normal | Normal | Normal | Normal signal | Normal signal |
| | | signal | | |
| Normal | Short | First fault | Normal signal | Normal signal |
| | | signal | | |
| Normal | Open | First fault | Second fault | Normal signal |
| | | signal | signal | |
| Abnormal | Normal | Normal | Normal signal | Third fault |
| heating | | signal | | signal |
| Abnormal | Short | First fault | Normal signal | Third fault |
| heating | | signal | | signal |
| Abnormal | Open | First fault | Second fault | Third fault |
| heating | | signal | signal | signal |

In the LED driving module 20 according to the embodiment of the present invention, the fault sensing unit 23 may output a normal signal or a fault signal through the first fault signal output terminal 27, the second fault signal output terminal 28, and the third fault signal output terminal 29 depending on the faulty state of the ultraviolet LED 11. Accordingly, it is possible to determine not only a fault of the ultraviolet LED 11, but also the type of fault that has occurred in the ultraviolet LED 11 depending upon combination of signals output from the first fault signal output terminal 27, the second fault signal output terminal 28, and the third fault signal output terminal 29.

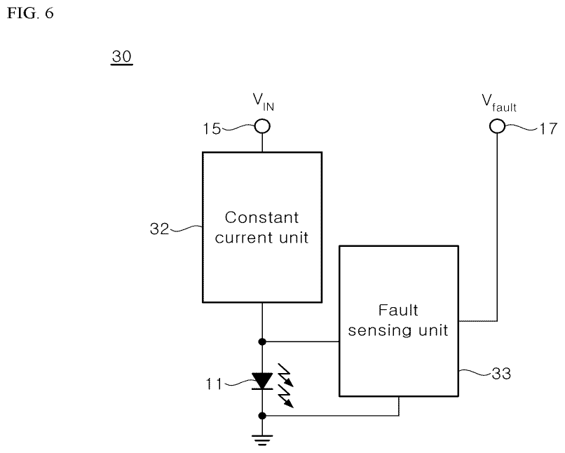

FIG. 6 is a schematic block diagram of an LED driving module according to a third embodiment of the present invention.

The LED driving module 10 according to the third embodiment may include an ultraviolet LED 11, a constant current unit 12, and a fault sensing unit 33.

Referring to FIG. 6, in the LED driving module 10 according to the third embodiment, the constant current unit 12 may be disposed at the front end of the ultraviolet LED 11. That is, the constant current unit 12 may be connected to a node between an input terminal to which a voltage is input and an anode terminal of the ultraviolet LED 11 and may control a current flowing in the ultraviolet LED 11.

The constant current unit 12 according to this embodiment may be realized by any circuit that is disposed at the front end of the ultraviolet LED 11 and may control the current of the ultraviolet LED 11.

In addition, the fault sensing unit 33 according to this embodiment may be configured with the circuit of the fault sensing unit 13 of the LED driving module 10 according to the first embodiment shown in FIG. 3 or the circuit of the fault sensing unit 23 of the LED driving module 20 according to the second embodiment shown in FIG. 5.

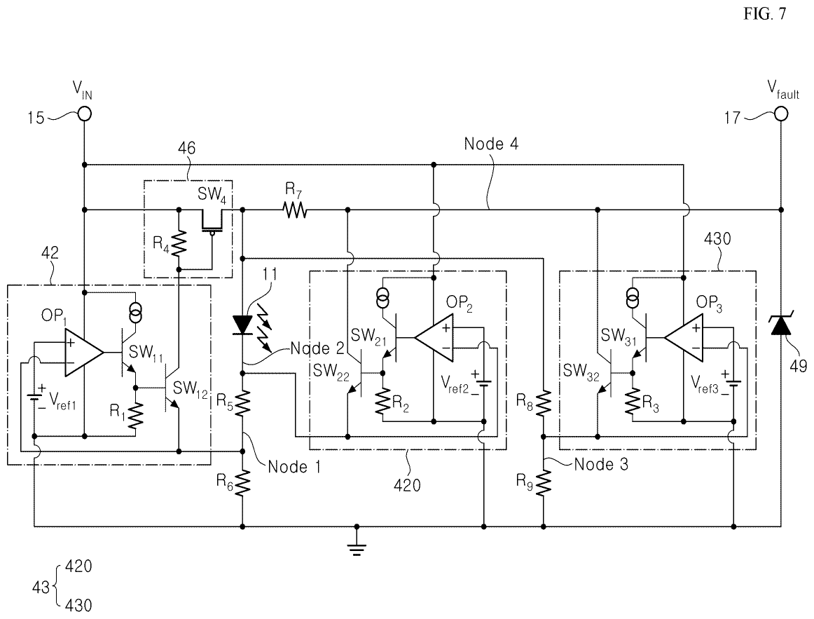

FIG. 7 is a circuit diagram of an LED driving module according to a fourth embodiment of the present invention.

Referring to FIG. 7, in the LED driving module 40 according to the fourth embodiment, a constant current unit 42 may be disposed at the front end of the ultraviolet LED 11.

The LED driving module 40 according to the fourth embodiment may include an ultraviolet LED 11, the constant current unit 42, a switch unit 46, and a fault sensing unit 43. In this embodiment, the fault sensing unit 43 may be a connection sensing unit. The fault sensing unit 43 may include an opening sensing unit 420 and a short sensing unit 430.

The constant current unit 42 according to this embodiment may control the switch unit 46 to supply a constant current to the ultraviolet LED 11. The switch unit 46 according to this embodiment may include a fourth switch SW₄ and a fourth resistor R₄. The fourth switch SW₄ may be a p-type MOSFET.

In the LED driving module 40 according to this embodiment, the opening sensing unit 420 and the short sensing unit 430 do not operate when the ultraviolet LED 11 is in a normal state. Further, in the LED driving module 40 according to this embodiment, the opening sensing unit 420 may operate when the ultraviolet LED 11 is in an open state and the short sensing unit 430 may operate when the ultraviolet LED 11 is in a short state.

Each of the constant current unit 42, the opening sensing unit 420, and the short sensing unit 430 according to this embodiment may include an amplifier, switches, and resistors.

Each of the amplifiers may be a negative feedback amplifier. In addition, a preset reference voltage and an input voltage may input to each of the amplifiers. Each of the amplifiers may compare an input voltage with an incoming reference voltage and may control a switch connected to the amplifier based on a comparison result. The amplifier may allow an output terminal to output a voltage depending upon the state of the ultraviolet LED 11 by controlling the switch.

Each of the switches may be an NPN-type bipolar transistor. The switch realized by the bipolar transistor may include a first end as a base terminal, a second end as a collector terminal, and a third end as an emitter terminal.

Referring to FIG. 7, the constant current unit 42 may include a first amplifier OP₁, a first switch SW₁₁, and a first-2 switch SW₁₂. The opening sensing unit 420 may include a second amplifier OP₂, a second-1 switch SW₂₁, and a second-2 switch SW₂₂. Further, the short sensing unit 430 may include a third amplifier OP₃, a third-1 switch SW₃₁, and a third-2 switch SW₃₂. The switches of the opening sensing unit 420 are opening sensing switches that operate according to an open state of the ultraviolet LED 11. Further, the switches of the short sensing unit 430 are short sensing switches that operate according to a short state of the ultraviolet LED 11.

Each of the first amplifier OP₁, the second amplifier OP₂, and the third amplifier OP₃ may compare an input voltage with a corresponding preset reference voltage and may output signals that turn on or turn off switches connected thereto depending upon a comparison result.

A fifth resistor R₅ and a sixth resistor R₆ are connected in series to the cathode terminal of the ultraviolet LED 11. The first amplifier OP₁ of the constant current unit 42 may be connected to a first node (Node 1) to which the fifth resistor R₅ and the sixth resistor R₆ are connected and may receive a first node voltage. The first node voltage is a voltage at the first node. The first amplifier OP₁ may compare the first node voltage with a preset reference voltage V_{ref1} and may output a signal to control the first-1 switch SW₁₁. Here, the signal controlling the first-1 switch SW₁₁ may be a voltage input to the first end, which is the base terminal of the first-1 switch SW₁₁. When the first switch SW₁₁ is turned on to increase a current flowing through the first resistor R₁, the voltage input to the first end of the second switch SW₁₂ increases. When the voltage input to the first end of the first-2 switch SW₁₂ is greater than or equal to the operation voltage, the first-2 switch SW₁₂ may also be turned on.

As such, the first amplifier OP₁ of the constant current unit 42 may control operation of the first-1 switch SW₁₁ and the first-2 switch SW₁₂ according to a result of comparing the first node voltage with the reference voltage V_{ref1}. In addition, the current flowing in the ultraviolet LED 11 may be controlled to be constant by controlling operation of the fourth switch SW₄ of the switch unit 46 according to operation of the constant current unit 42.

The second amplifier OP₂ of the opening sensing unit 420 may compare a second node voltage at a second node (Node 2), to which the cathode terminal of the ultraviolet LED 11 and the fifth resistor R₅ are connected, with a reference voltage V_{ref2}, and may control operation of the second-1 switch SW₂₁ and the second-2 switch SW₂₂ according to a comparison result. Here, the second node voltage is a voltage applied to the second node.

In addition, the third amplifier OP₃ of the short sensing unit 430 may compare a third node voltage of a third node (Node 3), to which an eighth resistor R₅ and a ninth resistor R₉ are connected, with a reference voltage V_{ref3}, and may control operation of the third-1 switch SW₃₁ and the third-2 switch SW₃₂ according to a comparison result. Here, the third node voltage is a voltage applied to the third node. When the ultraviolet LED 11 is in a normal state, input voltages to the second amplifier OP₂ of the opening sensing unit 420 and the third amplifier OP₃ of the short sensing unit 430 may be higher than the reference voltages thereof.

Here, since the input voltage to the second amplifier OP₂ is higher than the reference voltage V_{ref2}, the second amplifier OP₂ may output a lower voltage than the operation voltage of the second-1 switch SW₂₁ as a control signal to the second-2 switch SW₂₁. Upon receiving the control signal from the second amplifier OP_{2,} the second-1 switch SW₂₁ is kept in a turn-off state and thus the second-2 switch SW₂₂ is also kept in a turn-off state. Accordingly, when the ultraviolet LED 11 is in a normal state, the opening sensing unit 420 may be in an inactive state.

Furthermore, since the input voltage to the third amplifier OP₃ is higher than the reference voltage V_{ref3}, the third amplifier OP3 may output a lower voltage than the operation voltage of the third-1 switch SW₃₁ as a control signal to the third-1 switch SW₃₁. Upon receiving the control signal from the third amplifier OP₃, the third-1 switch SW₃₁ is kept in a turn-off state and thus the third-3 switch SW₃₃ is also kept in a turn-off state. Accordingly, when the ultraviolet LED 11 is in a normal state, the short sensing unit 430 may be in an inactive state.

As such, when the ultraviolet LED 11 is in a normal state, the fault signal output terminal 17 may output a normal signal, which is a voltage indicating that the ultraviolet LED 11 is in the normal state. Here, the magnitude of the normal signal may be preset. For example, the voltage corresponding to the normal signal may be set using the constant voltage characteristics of a Zener diode 49. That is, a Zener voltage of the Zener diode 49 may be output when the ultraviolet LED 11 is in the normal state. Here, the Zener voltage of the Zener diode 49 may have a difference distinguishable from the voltage output from the fault signal output terminal 17 when the ultraviolet LED 11 is in an open state or in a short state.

When the ultraviolet LED 11 is in a short state, the first node voltage is higher than the reference voltage V_{ref2} of the second amplifier OP₂. Here, the second-1 switch SW₂₁ may be kept in a turn-off state by a signal output from the second amplifier OP₂. In addition, the second switch SW₂₂ may also be kept in a turn-off state. That is, when the ultraviolet LED 11 is in a short state, the opening sensing unit 420 may be in an inactive state.

Here, the third node voltage may be set to be less than or equal to the reference voltage V_{ref3} of the third amplifier OP₃ by the eighth resistor R₅ and the ninth resistor R₉. Furthermore, when the ultraviolet LED 11 is in a short state, the third node voltage may be maintained at a preset voltage by a feedback system of the third amplifier OP₃. Here, the preset voltage may be the same as the reference voltage V_{ref3}.

The third amplifier OP₃ may output a signal that turns on the third-1 switch SW₃₁. Upon receiving the signal from the third amplifier OP₃, the third-1 switch SW₃₁ may be turned on and thus the third-2 switch SW₃₂ may also be turned on. As the third-2 switch SW₃₂ is turned on, a current flowing in the fourth node (Node 4), to which the seventh resistor R₇ and the Zener diode 49 are connected, flows through the third-2 switch SW₃₂.

Accordingly, when the ultraviolet LED 11 is in a short state, the fault signal output terminal 17 may output a voltage corresponding to a fault signal V_{fault}, as calculated according to Equation 2.

$${V}_{fault} = {V}_{CE 32} + {V}_{ref 3} \qquad [ Equation 2 ]$$

Here, V_{CE32} denotes V_{CE} of the third-2 switch SW₃₂.

Further, when the ultraviolet LED 11 is in a short state, the first node voltage and the third node voltage, which are the input voltages of the first amplifier OP₁ and the third amplifier OP₃, may be maintained at a preset voltage value by the feedback system of the first amplifier OP₁ and the second amplifier OP₂. For example, the preset voltage may be the same as the reference voltage of each amplifier.

When the ultraviolet LED 11 is in a short state, the third node voltage is set to be equal to the reference voltage V_{ref3} of the third amplifier OP₃ and V_{CE32} is also a voltage with a very small magnitude. Therefore, when the ultraviolet LED 11 is in a short state, a slightly higher voltage than the third node voltage may be output as a fault signal to the fault signal output terminal 17.

When the ultraviolet LED 11 is in an open state, the third node voltage may be higher than the reference voltage V_{ref3} of the third amplifier OP₃. Here, the third switch SW₃₁ may be turned off by a signal output from the third amplifier OP₃ and thus the third switch SW₃₂ may also be turned off. Accordingly, the short sensing unit 430 may be in an inactive state.

When the ultraviolet LED 11 is in an open state, the third node voltage V_{node 3} may be calculated according to Equation 3.

$${V}_{node 3} = {V}_{IN} \cdot ( {R}_{9} / ( {R}_{8} + {R}_{9} ) \qquad [ Equation 3 ]$$

In addition, when the ultraviolet LED 11 is in an open state, the first node voltage may be lower than the reference voltage V_{ref2} of the second amplifier OP₂. The second node voltage V_{node 2} may be calculated according to Equation 4.

$${V}_{node 2} = ( {V}_{ref 1} / {R}_{6} ) \cdot ( {R}_{5} + {R}_{6} ) \qquad [ Equation 4 ]$$

For example, when the ultraviolet LED 11 is in an open state, the first node voltage may be 0 V or a low voltage close to 0 V.

Upon receiving the first node voltage as an input voltage, the second amplifier OP₂ may output a signal that turns on the second-1 switch SW₂₁. Thus, the second-1 switch SW₂₁ and the second-2 switch SW₂₂ may also be sequentially turned on. When the second-2 switch SW₂₂ is turned on, the current may be rerouted to pass through the second-2 switch SW₂₂.

Here, when the ultraviolet LED 11 is in an open state, the fault signal output terminal 17 may output a voltage corresponding to a fault signal V_{fault}, as calculated according to Equation 5.

$${V}_{fault} = {V}_{node 2} + {V}_{CE 22} \qquad [ Equation 5 ]$$

Here, V_{CE22} is V_{CE} of the second-2 switch SW₂₂.

When the ultraviolet LED 11 is in an open state, V_{node 2} is 0 V or a very low voltage close to 0 V and V_{CE22} is also a very low voltage. Accordingly, when the ultraviolet LED 11 is in an open state, a very low voltage close to 0 V may be output as a fault signal from the fault signal output terminal 17.

According to this embodiment, when the ultraviolet LED 11 is in a faulty state as in a short state or in an open state, the fault signal output from the fault signal output terminal 17 may be a lower voltage than when the ultraviolet LED 11 is in a normal state. For example, when the ultraviolet LED 11 is in a faulty state, the fault signal output terminal 17 may output a smaller voltage than the Zener voltage of the Zener diode 49.

As such, the LED driving module 40 according to this embodiment may output a preset voltage, such as a Zener voltage, through the fault signal output terminal 17 when the ultraviolet LED 11 is in a normal state, and may output a lower voltage than the Zener voltage through the fault signal output terminal 17 when the ultraviolet LED 11 is in an abnormal state. Accordingly, the state of the ultraviolet LED 11 may be determined according to the magnitude of the output voltage of the LED driving circuit according to this embodiment.

The LED driving module 40 according to this embodiment applies an amplifier to each of the opening sensing unit 420 and the short sensing unit 430 and uses a reference voltage within the amplifier to sense a short state and an open state of the ultraviolet LED 11. The LED driving module 40 according to this embodiment employs an amplifier with a small deviation due to a surrounding environment, such as temperature change, thereby minimizing deviation of an output voltage due to change in surrounding environment. Accordingly, the LED driving module 40 according to this embodiment can prevent an error of incorrectly determining failure of the LED driving module 40 by minimizing the deviation of the voltage to be used to determine the fault of the ultraviolet LED 11.

In this embodiment, the fourth switch SW₄ of the switch unit 46 is described as a P-type MOSFET by way of example. However, it should be understood that the type of the fourth switch SW₄ is not limited thereto. The fourth switch SW₄ of the switch unit 46 can be any device capable of being turned on and off according to an input value. In addition, the switches of the constant current unit 42, the opening sensing unit 420, and the short sensing unit 430 may be any devices capable of being turned on and off according to input signals.

Further, the LED driving module 40 according to this embodiment may further include a heat sensing unit as described in the LED driving module according to the above embodiments.

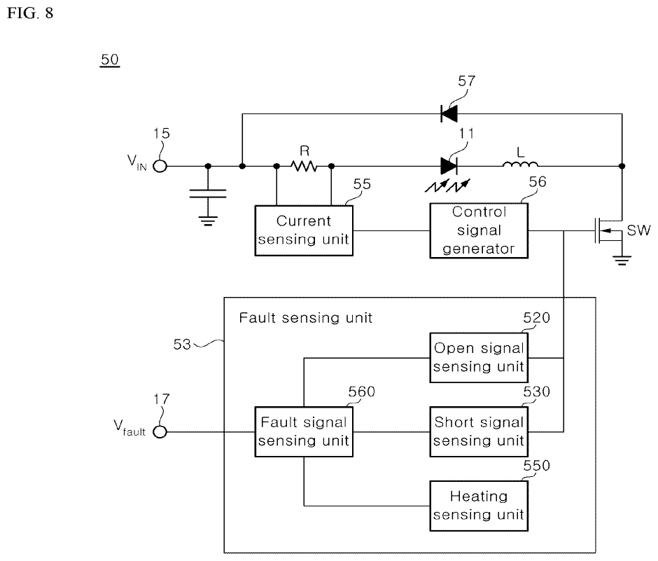

FIG. 8 is a block diagram of an LED driving module according to a fifth embodiment of the present invention.

Referring to FIG. 8, the LED driving module 50 according to the fifth embodiment of the present invention may include a current sensing unit 55, a control signal generator 56, and a fault sensing unit 53.

The current sensing unit 55 may sense a current supplied to the ultraviolet LED 11.

The control signal generator 56 may generate a control signal to control a switch SW according to the current sensed by the current sensing unit 55. The control signal generator 56 may generate a short signal that turns on the switch SW and an open signal that turns off the switch SW.

The switch SW may be turned on or turned off according to a control signal received from the control signal generator 56. When the switch SW is turned off in response to the open signal, a current may flow along a node to which an ultraviolet LED 11, an inductor L, and a diode 57 are connected. When the switch SW is turned on in response to the short signal, a current may flow along the node to which the ultraviolet LED 11, the inductor L, and the switch SW are connected.

The fault sensing unit 53 may include a heat sensing unit 550, an open signal sensing unit 520, a short signal sensing unit 530, and a fault signal generator 560.

The heat sensing unit 550 according to this embodiment may sense the degree of heating of the ultraviolet LED 11. The heat sensing unit may sense the temperature of the ultraviolet LED 11 or an ambient temperature and may send a signal corresponding to the sensed temperature to the fault signal generator 560. The fault signal generating unit 560 may generate and output a fault signal indicating a fault of the ultraviolet LED 11 in response to the signal received from the heat sensing unit 550. For example, the fault signal generator 560 may generate and output a fault signal when the temperature sensed by the heat sensing unit 550 is higher than or equal to a predetermined temperature.

The open signal sensing unit 520 and the short signal sensing unit 530 may sense a control signal sent from the control signal generator 56 to the switch SW.

The open signal sensing unit 520 may sense an open signal that the control signal generator 56 sends to the switch SW.

For example, when the ultraviolet LED 11 is in a short state, a current continuously flows in a node to which the current sensing unit 55 is connected. That is, a current having a certain magnitude may be continuously sensed by the current sensing unit 55. Here, the control signal generator 56 may generate and send an open signal to the switch SW while the current sensing unit 55 senses the current having an arbitrary magnitude.

The open signal sensing unit 520 may sense the open signal from the control signal generator 56 and may send a corresponding signal to the fault signal generator 560. Here, the fault signal generator 560 may determine that the ultraviolet LED 11 is in a short state when the open signal sensing unit 520 senses the open signal for a preset period of time or more. Accordingly, the fault signal generator 560 may generate and output a fault signal indicating a fault of the ultraviolet LED 11 when the control signal generator 56 generates the open signal for a preset period of time or more.

The short signal sensing unit 530 may sense a short signal that the control signal generator 56 sends to the switch SW.

For example, when the ultraviolet LED 11 is in an open state, no current flows in the node to which the current sensing unit 55 is connected. Here, the control signal generator 56 may generate and send a short signal to the switch SW in order to allow a current to flow to the ultraviolet LED 11. However, since the ultraviolet LED 11 is in the open state, the current sensing unit 55 cannot sense the current even when the switch SW is in a short state. Accordingly, the control signal generator 56 continuously generates and transmits the short signal to the switch SW.

The short signal sensing unit 530 may sense the short signal from the control signal generator 56 and may send a corresponding signal to the fault signal generator 560. Here, the fault signal generator 560 may determine that the ultraviolet LED 11 is in an open state when the short signal sensing unit 530 senses the short signal for a preset period of time or more. Accordingly, the fault signal generator 560 may generate and output a fault signal indicating a fault of the ultraviolet LED 11 when the control signal generator 56 generates the short signal for a preset period of time or more.

As such, the LED driving module 50 according to this embodiment may sense a control signal of the control signal generator 56, which controls the switch SW, and may sense a fault of the ultraviolet LED 11 based on the type of control signal and a period of time for which the control signal is sent to the switch SW.

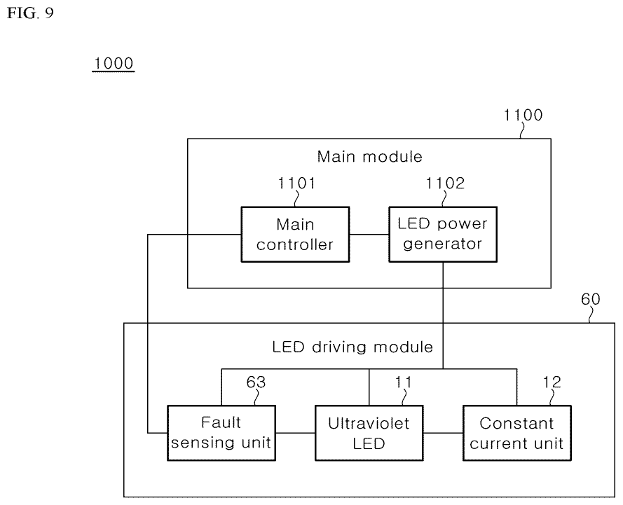

FIG. 9 is a schematic block diagram of a system of an ultraviolet LED device according to an embodiment of the present invention.

Referring to FIG. 9, a system 1000 of an ultraviolet LED device according to one embodiment may include a main module 1100 and an LED driving module 60.

The main module 1100 may be configured to control an overall operation of a product to which the ultraviolet LED 11 and the LED driving module 60 are applied.

In the system 1000 of the ultraviolet LED device according to this embodiment, the main module 1100 may include a main controller 1101 and an LED power generator 1102.

The main controller 1101 may control the overall operation of the product. The main controller 1101 may generate signals for various operations of the product. In addition, the main controller 1101 may supply power for operation of the components of the product to each component. Furthermore, the main controller 1101 may supply power to the LED power generator 1102.

The LED power generator 1102 may generate LED driving power for operation of the ultraviolet LED 11 and the LED driving module 60. For example, the LED power generator 1102 may convert alternating current power supplied from the main controller 1101 into direct current power to generate the LED driving power. The LED power generator 1102 may also include a filter to block noise, a power factor correction circuit configured to correct a power factor of a power source, and the like.

The driving power generated by the LED power generator 1102 may be supplied to the LED driving module 60.

The LED driving module 60 according to this embodiment may be any of the LED driving modules 10, 20, 30, 40, 50 according to the first to fifth embodiments described with reference to FIG. 1 to FIG. 8.

The LED driving module 60 may supply the driving power received from the LED power generator 1102 to the ultraviolet LED 11 to allow the ultraviolet LED 11 to emit UV light. In addition, the LED driving module 60 may supply the driving power to other components in addition to the ultraviolet LED 11.

The LED driving module 60 may include a constant current unit 12 for stable driving of the ultraviolet LED 11 and a fault sensing unit 63 configured to sense a fault of the ultraviolet LED 11.

The fault sensing unit 63 may generate and send a fault signal, indicating that a fault, such as overheating, short, or opening of the ultraviolet LED 11, has occurred in the ultraviolet LED 11, to the main controller 1101.

When the main controller 1101 receives a fault signal from the fault sensing unit 63, the main controller 1101 may output a corresponding signal such that the signal can be visually or audibly confirmed outside the product. For example, the main controller 1101 may indicate a fault of the ultraviolet LED 11 through a display device provided to the product. In addition, the main controller 1101 may output an audible sound through a speaker installed in the product to indicate the fault of the ultraviolet LED 11.

For example, the LED driving module 60 according to this embodiment may be the LED driving module 20 according to the second embodiment shown in FIG. 5. The fault sensing unit 63 of the LED driving module 60 may send each of the signals output through the first to third fault signal output terminals 27, 28, 29 (see FIG. 5) to the main controller 1101.

The main controller 1101 may determine the state of the ultraviolet LED 11 by combining the signals received from the first to third fault signal output terminals 27, 28, 29 (see FIG. 5) of the fault sensing unit 63, respectively. For example, the main controller 1101 may determine whether the ultraviolet LED 11 undergoes any one of abnormal heating, short, and opening or combinations thereof.

The main controller 1101 may output a signal corresponding to the results of the output terminals of the fault sensing unit 63 to the outside of the product through a device in the product such that the fault of the ultraviolet LED 11 can be visually or audibly recognized outside the product.

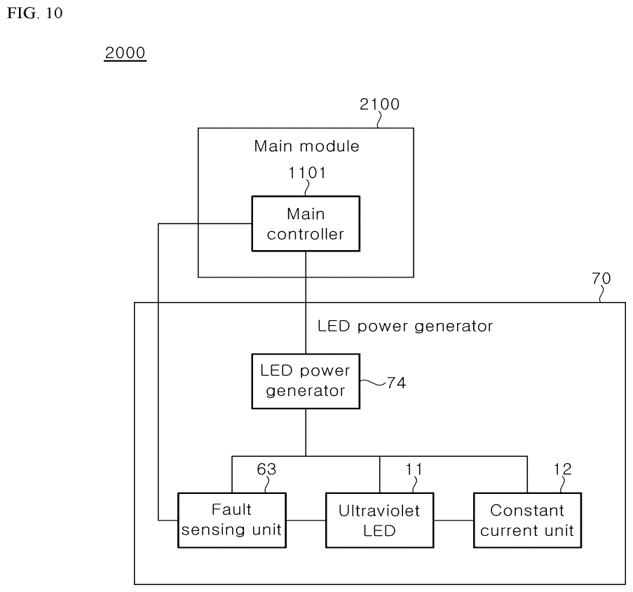

FIG. 10 is a block diagram of a system of an ultraviolet LED device according to another embodiment of the present invention.

The system 2000 of the ultraviolet LED device according to this embodiment may include a main module 2100 and an LED driving module 70.

The system 2000 of the ultraviolet LED device according to this embodiment is different from the system 1000 of the ultraviolet LED device shown in FIG. 9 in that the LED driving module 70 includes an LED power generator 74.

The LED driving module 70 according to this embodiment may convert alternating current power supplied from the main controller 1101 into direct current power. That is, the LED driving module 70 according to this embodiment may include the LED power generator 74. The LED power generator 74 of the LED driving module 70 may convert the power supplied from the main controller 1101 of the main module 2100 into drive power for operation of the ultraviolet LED 11 and other components.

The other components of the LED device system 2000 according to this embodiment are the same as those of the ultraviolet LED device system 1000 shown in FIG. 9 except that the LED driving module 70 includes the LED power generator 74.

The LED driving modules described above in various embodiments of the present invention may be applied to small products each provided with a single ultraviolet LED.

The LED driving module according to the embodiments of the present invention may include the fault sensing unit capable of detecting faults in the ultraviolet LED. Accordingly, the LED driving module may sense various faults that can occur in the ultraviolet LED, and may further generate a signal enabling determination of a detailed kind of fault.

In addition, according to the embodiments of the present invention, the LED driving module can realize the fault sensing unit through a simple circuit, thereby minimizing increase in size of the LED driving module. Thus, the LED driving module according to the embodiments of the invention may generate a signal indicating a fault of the ultraviolet LED while maintaining a size suitable for small products.

Although some embodiments have been described herein with reference to the accompanying drawings, it should be understood that the above embodiments are provided for illustration only and are not to be in any way construed as limiting the present invention. The scope of the present invention should be defined by the appended claims and equivalents thereto.

1. An LED driving module provided with an ultraviolet LED, comprising:
a fault sensing unit configured to sense a fault in the ultraviolet LED,
wherein the fault sensing unit comprises a connection sensing unit configured to sense a connection state of the ultraviolet LED,
the connection sensing unit being configured to output a fault signal through a fault signal output terminal when a fault occurs due to a short state or opening state of the ultraviolet LED.

2. The LED driving module according to claim 1, wherein
the connection sensing unit comprises a connection sensing switch turned on and turned off according to a voltage of a node connected to the ultraviolet LED.

3. The LED driving module according to claim 2, wherein
the node connected to the ultraviolet LED is connected to an anode terminal of the ultraviolet LED, and
the connection sensing switch comprises:
a first end to which a voltage corresponding to the node voltage is applied to turn on and turn off the connection sensing switch;
a second end connected to the fault signal output terminal; and
a third end connected to ground.

4. The LED driving module according to claim 3, wherein
the fault signal output terminal comprises:
a first fault signal output terminal outputting a first fault signal when the ultraviolet LED is in the short state; and
a second fault signal output terminal outputting a second fault signal when the ultraviolet LED is in the open state.

5. The LED driving module according to claim 4, wherein
the first fault signal output terminal is connected to a node connecting the second end of the connection sensing switch to one end of a resistor,
the second fault signal output terminal is connected to a node connecting two resistors in series between the anode terminal of the ultraviolet LED and ground, and
the resistor connected to the second end of the connection sensing switch is connected at the other end thereof to ground.

6. The LED driving module according to claim 3, wherein
the fault sensing unit further comprises a heat sensing unit configured to sense a heating state of the ultraviolet LED.

7. The LED driving module according to claim 6, wherein
the heat sensing unit comprises: a thermal resistor whose resistance varies depending upon ambient temperature; and a heat sensing switch connected to the thermal resistor,
the thermal resistor being connected to the anode terminal of the ultraviolet LED,
the heat sensing switch being turned on and turned off in response to a voltage varying according to resistance of the thermal resistor.

8. The LED driving module according to claim 7, wherein
the heat sensing switch comprises:
a first end receiving a voltage varying according to resistance of the thermal resistor;
a second end connected to the fault signal output terminal; and
a third end connected to ground.

9. The LED driving module according to claim 8, wherein
the fault signal output terminal comprises:
a first fault signal output terminal outputting a first fault signal when the ultraviolet LED is in the short state;
a second fault signal output terminal outputting a second fault signal when the ultraviolet LED is in the open state; and
a third fault signal output terminal outputting a third fault signal when the ultraviolet LED is in the overheating state.

10. The LED driving module according to claim 9, wherein
the first fault signal output terminal is connected to a node connecting the second end of the connection sensing switch and one end of a resistor,
the second fault signal output terminal is connected to a node connecting two resistors in series between the anode terminal of the ultraviolet LED and ground,
the third fault signal output terminal is connected to a node connecting the second end of the heat sensing switch to one end of a resistor, and
each of the resistor connected to the second end of the connection sensing switch and the resistor connected to the second end of the heat sensing switch is connected at the other end thereof to ground.

11. The LED driving module according to claim 2, wherein
the connection sensing unit comprises:
an opening sensing unit configured to sense the open state of the ultraviolet LED; and
a short sensing unit configured to sense the short state of the ultraviolet LED.

12. The LED driving module according to claim 11, wherein
each of the opening sensing unit and the short sensing unit comprises:
an amplifier configured to compare a reference voltage with an input voltage; and
at least a switch turned on and turned off by an output signal of the amplifier.

13. The LED driving module according to claim 12, wherein
the opening sensing unit comprises an opening sensing switch,
the opening sensing switch comprising:
a first end receiving a voltage for turning on and turning off the switch in response to a signal output from the amplifier of the opening sensing unit;
a second end connected to the fault signal output terminal; and
a third end through which a current input through the first end passes when the opening sensing switch is in a turn-on state.

14. The LED driving module according to claim 12, wherein
the short sensing unit comprises a short sensing switch,
the short sensing switch comprising:
a first end receiving a voltage for turning on and turning off the switch in response to a signal output from the amplifier of the short sensing unit;
a second end connected to the fault signal output terminal; and
a third end through which a current input through the first end passes when the short sensing switch is in a turn-on state.

15. The LED driving module according to claim 11, wherein
the fault signal output terminal outputs a normal signal when the ultraviolet LED is in a normal state.

16. The LED driving module according to claim 15, wherein
the fault signal is a lower voltage than the normal signal.

17. The LED driving module according to claim 15, further comprising:
a Zener diode connected at one end thereof to the fault signal output terminal and at the other end thereof to ground,
wherein the normal signal is a Zener voltage.

18. The LED driving module according to claim 1, further comprising:
a current sensing unit configured to sense a current supplied to the ultraviolet LED; and
a control signal generator configured to generate and output a signal to control a switch according to the current sensed by the current sensing unit;
wherein the control signal generator outputs a short signal and an open signal to the switch, the short signal turning on the switch, the open signal turning off the switch,
the connection sensing unit senses the short signal and the open signal output from the control signal generator to the switch, and
the fault sensing unit generates and outputs a fault signal when the short signal or the open signal sensed by the connection sensing unit is sensed for a preset period of time or more.

19. The LED driving module according to claim 18, wherein
the fault sensing unit further comprises a heat sensing unit configured to sense a temperature of the ultraviolet LED or an ambient temperature of the ultraviolet LED, and
the fault sensing unit generates and outputs a fault signal when the temperature sensed by the heat sensing unit is greater than or equal to a preset temperature.

20. The LED driving module according to claim 1, further comprising:
a constant current unit configured to supply a constant current to the ultraviolet LED.
